(19) United States
(12) Patent Application Publication
(10) Pub. No.: US 2025/0331218 A1
(43) Pub. Date: Oct. 23, 2025

(54) SEMICONDUCTOR TRANSISTOR STRUCTURE AND FABRICATION METHOD THEREOF

(71) Applicant: UNITED MICROELECTRONICS CORP., Hsin-Chu City (TW)

(72) Inventors: Ming-Hsiang Tu, Tainan City (TW); Ming-Hua Tsai, Tainan City (TW); Chun-Lin Chen, Tainan City (TW); Chun-Wen Cheng, New Taipei City (TW); Ya-Hsin Huang, Tainan City (TW); Yung-Fang Yang, Chiayi City (TW)

(73) Assignee: UNITED MICROELECTRONICS CORP., Hsin-Chu City (TW)

(21) Appl. No.: 18/733,871

(22) Filed: Jun. 5, 2024

(30) Foreign Application Priority Data
Apr. 17, 2024 (TW) 113114219

(51) Int. Cl. H01L 29/78; H01L 29/66

(52) U.S. Cl. CPC H10D 30/601; H10D 30/022

(57) ABSTRACT

A semiconductor transistor structure includes a substrate; an active region located on the substrate and surrounded by a trench isolation region; a source structure located in the active region, including a source LDD region and a heavily doped source region; a drain structure located in the active region and spaced apart from the source structure, wherein the drain structure includes a drain LDD region and a heavily doped drain region; a gate structure located on the active region and between the source structure and the drain structure; and a first embedded epitaxial structure disposed in the drain LDD region and located between the gate structure and the heavily doped drain region.

### BACKGROUND OF THE INVENTION

### 1. Field of the Invention

The present invention relates to the field of semiconductor technology, and in particular to a medium-voltage metal-oxide-semiconductor (MVMOS) transistor structure and a manufacturing method thereof.

### 2. Description of the Prior Art

As the semiconductor process evolves, the thickness of the sidewall spacer of the transistor gate structure is also reduced, which causes the embedded medium-voltage transistor device fabricated using 14 nm process to face gate-induced drain leakage current (GIDL) problem. In addition, the embedded medium-voltage transistor devices in the prior art occupy a large chip area, and there is still a need for further reduction.

Therefore, there is still a need for further improvements in the structure of medium-voltage metal oxide semiconductor transistors in this technical field.

### SUMMARY OF THE INVENTION

It is one object of the present invention to provide an improved semiconductor transistor structure and a manufacturing method thereof in order to solve the deficiencies or shortcomings of the existing technology.

One aspect of the invention provides a semiconductor transistor structure including a substrate having a first conductivity type; an active area on the substrate, wherein the active area is surrounded by a trench isolation region; a source structure in the active area, wherein the source structure comprises a source lightly doped drain (LDD) region having a second conductivity type and a heavily doped source region having the second conductivity type within the source LDD region; a drain structure in the active area and spaced apart from the source structure, wherein the drain structure comprises a drain lightly doped drain (LDD) region having the second conductivity type and a heavily doped drain region having the second conductivity type within the drain LDD region; a gate structure on the active area and between the source structure and the drain structure; and a first embedded epitaxial structure disposed in the drain LDD region and between the gate structure and the heavily doped drain region.

According to some embodiments, the first embedded epitaxial structure comprises an undoped epitaxial SiGe layer or an undoped epitaxial SiP layer.

According to some embodiments, the first embedded epitaxial structure comprises an epitaxial SiGe layer or an epitaxial SiP layer doped with dopants having the first conductivity type.

According to some embodiments, the first embedded epitaxial structure has a thickness that is smaller than a junction depth of the drain LDD region.

According to some embodiments, the first embedded epitaxial structure has a thickness that is greater than or equal to a junction depth of the drain LDD region.

According to some embodiments, the gate structure comprises a first sidewall spacer, wherein the first sidewall spacer overlaps with the drain LDD region.

According to some embodiments, the first embedded epitaxial structure is disposed between the first sidewall spacer and the heavily doped drain region.

According to some embodiments, the semiconductor transistor structure further includes a drain silicide layer disposed on the heavily doped drain region, wherein the drain silicide layer is not in direct contact with the first embedded epitaxial structure.

According to some embodiments, the semiconductor transistor structure further includes a second embedded epitaxial structure disposed in the source LDD region and between the gate structure and the heavily doped source region.

According to some embodiments, the second embedded epitaxial structure comprises an epitaxial SiGe layer or an epitaxial SiP layer.

Another aspect of the invention provides a method for forming a semiconductor transistor structure. A substrate having a first conductivity type is provided. An active area is formed on the substrate. The active area is surrounded by a trench isolation region. A source structure is formed in the active area. The source structure includes a source lightly doped drain (LDD) region having a second conductivity type and a heavily doped source region having the second conductivity type within the source LDD region. A drain structure is formed in the active area and spaced apart from the source structure. The drain structure includes a drain lightly doped drain (LDD) region having the second conductivity type and a heavily doped drain region having the second conductivity type within the drain LDD region. A gate structure is formed on the active area and between the source structure and the drain structure. A first embedded epitaxial structure is formed in the drain LDD region and between the gate structure and the heavily doped drain region.

According to some embodiments, the first embedded epitaxial structure comprises an undoped epitaxial SiGe layer or an undoped epitaxial SiP layer.

According to some embodiments the first embedded epitaxial structure comprises an epitaxial SiGe layer or an epitaxial SiP layer doped with dopants having the first conductivity type.

According to some embodiments the first embedded epitaxial structure has a thickness that is smaller than a junction depth of the drain LDD region.

According to some embodiments the first embedded epitaxial structure has a thickness that is greater than or equal to a junction depth of the drain LDD region.

According to some embodiments the gate structure comprises a first sidewall spacer, wherein the first sidewall spacer overlaps with the drain LDD region.

According to some embodiments the first embedded epitaxial structure is disposed between the first sidewall spacer and the heavily doped drain region.

According to some embodiments, the method further includes the step of forming a drain silicide layer disposed on the heavily doped drain region. The drain silicide layer is not in direct contact with the first embedded epitaxial structure.

According to some embodiments, the method further includes the step of forming a second embedded epitaxial structure disposed in the source LDD region and between the gate structure and the heavily doped source region.

According to some embodiments, the second embedded epitaxial structure comprises an epitaxial SiGe layer or an epitaxial SiP layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic top view of a semiconductor transistor structure according to an embodiment of the present invention.

FIG. 2 is a schematic cross-sectional view along line I-I′ in FIG. 1.

FIG. 3 and FIG. 4 are partial enlarged views of the semiconductor transistor structure.

FIG. 5 to FIG. 8 are schematic diagrams of a method of forming a semiconductor transistor structure according to an embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

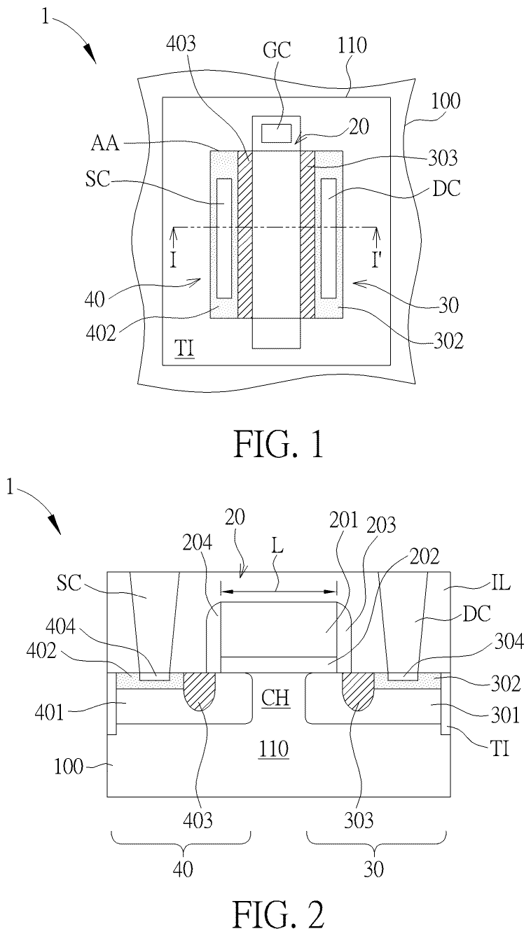

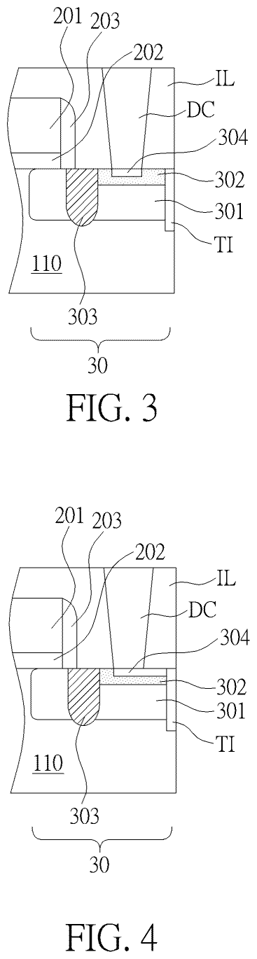

Please refer to FIG. 1 and FIG. 2. FIG. 1 is a schematic top view of a semiconductor transistor structure according to an embodiment of the present invention, and FIG. 2 is a schematic cross-sectional view along line I-I′ in FIG. 1. As shown in FIG. 1 and FIG. 2, the semiconductor transistor structure 1 includes a substrate 100 having a first conductivity type. For example, the first conductivity type may be P type, and the substrate 100 may be a silicon substrate, but is not limited thereto. An active area AA is formed in the substrate 100, where the active area AA may be located in an ion well 110 having the first conductivity type. For example, the ion well 110 is a P-type well. The active area AA is surrounded by a trench isolation region TI. A source structure 40 and a drain structure 30 spaced apart from the source structure 40 are formed in the active area AA.

According to an embodiment of the present invention, a gate structure 20 is formed above the active area AA and is located between the source structure 40 and the drain structure 30. A channel region CH is defined in the substrate 100 directly below the gate structure 20. The channel region CH is located between the source structure 40 and the drain structure 30.

According to an embodiment of the present invention, the gate structure 20 includes a gate 201, a gate dielectric layer 202 located between the gate 201 and the channel region CH, a first sidewall spacer 203 and a second sidewall spacer 204 located on two opposite sidewalls of the gate 201. According to an embodiment of the present invention, for example, the first sidewall spacer 203 and the second sidewall spacer 204 may include silicon oxide, silicon nitride, silicon oxynitride, or a combination thereof. According to an embodiment of the present invention, for example, the gate 201 may include polysilicon or metal. According to an embodiment of the present invention, the operating voltage of the gate 201 can be provided through a gate contact GC.

According to an embodiment of the present invention, the drain structure 30 includes a drain lightly doped drain (LDD) region 301 with a second conductivity type and a heavily doped drain region 302 with the second conductivity type located within the drain LDD region 301. The first sidewall spacer 203 may overlap the drain LDD region 301. According to an embodiment of the present invention, the source structure 40 includes a source LDD region 401 with the second conductivity type and a heavily doped source region 402 with the second conductivity type located within the source LDD region 401. The second sidewall spacer 204 may overlap the source LDD region 401. According to an embodiment of the present invention, for example, the second conductivity type may be N-type. According to an embodiment of the present invention, the gate 201 may partially overlap the drain LDD region 301 and the source LDD region 401.

According to an embodiment of the present invention, the drain structure 30 includes a first embedded epitaxial structure 303 in the drain LDD region 301 and between the gate structure 20 and the heavily doped drain region 302. According to an embodiment of the present invention, the first embedded epitaxial structure 303 is disposed between the first sidewall spacer 203 and the heavily doped drain region 302. According to an embodiment of the present invention, the source structure 40 includes a second embedded epitaxial structure 403 in the source LDD region 401 and between the gate structure 20 and the heavily doped source region 402. According to an embodiment of the present invention, the second embedded epitaxial structure 403 is disposed between the second sidewall spacer 204 and the heavily doped source region 402. In some embodiments, the second embedded epitaxial structure 403 can be omitted, so that the drain structure 30 and the source structure 40 are asymmetric structures relative to the gate structure 20.

According to an embodiment of the present invention, the first embedded epitaxial structure 303 and the second embedded epitaxial structure 403 may include an undoped epitaxial SiGe layer or an undoped epitaxial SiP layer. In some embodiments, the first embedded epitaxial structure 303 and the second embedded epitaxial structure 403 may include an epitaxial SiGe layer or an epitaxial SiP layer doped with dopants having the first conductivity type.

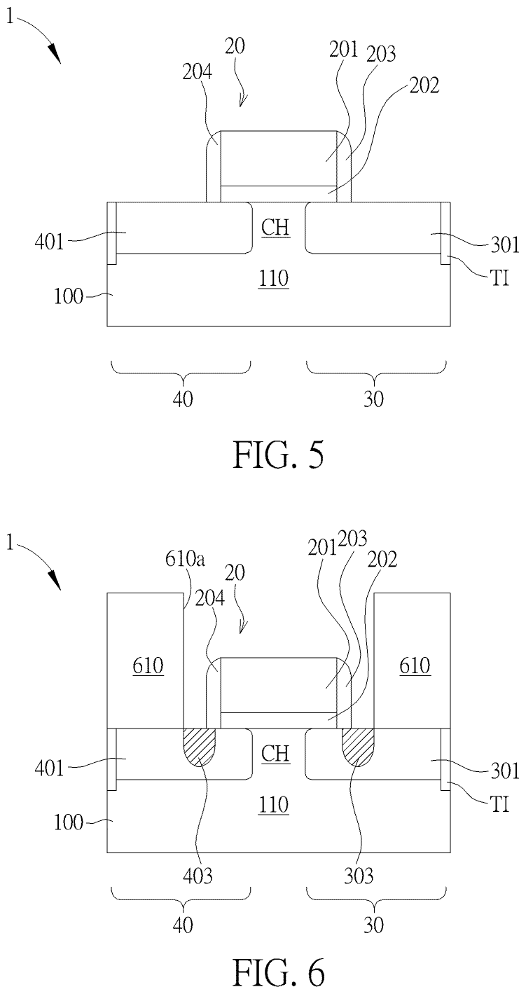

According to an embodiment of the present invention, the thickness of the first embedded epitaxial structure 303 is smaller than the junction depth of the drain LDD region 301, and the thickness of the second embedded epitaxial structure 403 is smaller than the junction depth of the source LDD region 401. In some embodiments, as shown in FIG. 3, the thickness of the first embedded epitaxial structure 303 is greater than or equal to the junction depth of the drain LDD region 301, and the thickness of the second embedded epitaxial structure 403 is greater than or equal to the junction depth of the source LDD region 401.

According to an embodiment of the present invention, the semiconductor transistor structure 1 further includes a drain silicide layer 304 disposed on the heavily doped drain region 302. The drain silicide layer 304 is not in direct contact with the first embedded epitaxial structure 303. According to an embodiment of the present invention, the semiconductor transistor structure 1 further includes a source silicide layer 404 disposed on the heavily doped source region 402. The source silicide layer 404 is not in direct contact with the second embedded epitaxial structure 403.

According to an embodiment of the present invention, the semiconductor transistor structure 1 further includes an interlayer dielectric layer IL. A drain contact DC and a source contact SC such as tungsten contact plugs are formed in the interlayer dielectric layer IL. According to an embodiment of the present invention, the drain contact DC and the source contact SC are located on the drain silicide layer 304 and the source silicide layer 404 respectively. According to an embodiment of the present invention, for example, the drain silicide layer 304 and the source silicide layer 404 may include CoSi₂, TiSi₂, WSi₂, NiSi₂, MoSi₂, and TaSi₂, but are not limited thereto. In some embodiments, as shown in FIG. 4, the drain silicide layer 304 may extend toward the trench isolation region TI, but the drain silicide layer 304 is still not in direct contact with the first embedded epitaxial structure 303.

It is one advantage of the present invention that the first embedded epitaxial structure 303 in the drain structure 30 is used to improve the GIDL problem faced by embedded medium-voltage transistor devices fabricated by using the 14-nm process. In addition, by adopting the structure of the present invention, a shorter gate length L can be achieved, so the chip area occupied by the embedded medium-voltage transistor device can be reduced.

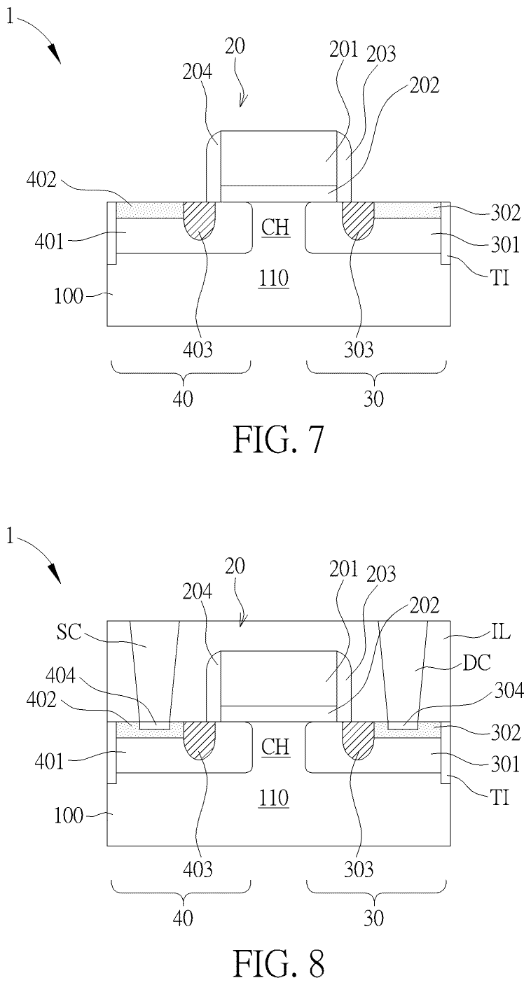

Please refer to FIG. 5 to FIG. 8, which are schematic diagrams of a method of forming a semiconductor transistor structure according to an embodiment of the present invention, wherein like regions, layers or elements are designated by like numeral numbers or labels. As shown in FIG. 5, after the gate structure 20 is formed on the substrate 100 of a first conductivity type, a photolithography process and an ion implantation process are then performed to form a drain LDD region 301 and a source LDD region 401 of a second conductivity type in the substrate 100.

According to an embodiment of the present invention, the gate structure 20 includes a gate 201, a gate dielectric layer 202 located between the gate 201 and the channel region CH, a first sidewall spacer 203 and second sidewall spacer 204 located on two opposite sidewalls of the gate 201. According to an embodiment of the present invention, for example, the first sidewall spacer 203 and the second sidewall spacer 204 may include silicon oxide, silicon nitride, silicon oxynitride, or a combination thereof. According to an embodiment of the present invention, for example, the gate 201 may include polysilicon or metal.

As shown in FIG. 6, a photolithography process and an etching process are then performed to form a patterned mask layer 610 on the substrate 100. The patterned mask layer 610 includes an opening 610a exposing the gate 201, the first sidewall spacer 203, and the second sidewall spacer 204 and parts of the drain LDD region 301 and the source LDD region 401 adjacent to the first sidewall spacer 203 and the second sidewall spacer 204. An etching process is then performed to respectively form a drain trench 301t and a source trench 401t in the drain LDD region 301 and the source LDD region 401 in a self-aligned manner. An epitaxial process is then performed to form a first embedded epitaxial structure 303 and a second embedded epitaxial structure 403 in the drain trench 301t and the source trench 401t respectively. Subsequently, the patterned mask layer 610 is removed.

According to an embodiment of the present invention, the first embedded epitaxial structure 303 and the second embedded epitaxial structure 403 may include an undoped epitaxial SiGe layer or an undoped epitaxial SiP layer. In some embodiments, the first embedded epitaxial structure 303 and the second embedded epitaxial structure 403 may include an epitaxial SiGe layer or an epitaxial SiP layer doped with dopants having the first conductivity type (e.g., P-type).

As shown in FIG. 7, a photolithography process and an ion implantation process are then performed to form a heavily doped drain region 302 with the second conductivity type in the drain LDD region 301, and a heavily doped source region 402 with the second conductivity type in the source LDD region 401.

As shown in FIG. 8, a chemical vapor deposition (CVD) process is then performed to deposit an interlayer dielectric layer IL on the substrate 100 in a blanket manner, and then a metallization process is performed to form a drain silicide layer 304 and source silicide layer 404 as well as drain contact DC and source contact SC on the substrate 100 and in the interlayer dielectric layer IL. According to an embodiment of the present invention, the drain silicide layer 304 located under the drain contact DC is not in direct contact with the first embedded epitaxial structure 303, and the source silicide layer 404 located under the source contact SC is not in direct contact with the second embedded epitaxial structure 403.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor transistor structure, comprising:
a substrate having a first conductivity type;
an active area on the substrate, wherein the active area is surrounded by a trench isolation region;
a source structure in the active area, wherein the source structure comprises a source lightly doped drain (LDD) region having a second conductivity type and a heavily doped source region having the second conductivity type within the source LDD region;
a drain structure in the active area and spaced apart from the source structure, wherein the drain structure comprises a drain lightly doped drain (LDD) region having the second conductivity type and a heavily doped drain region having the second conductivity type within the drain LDD region;
a gate structure on the active area and between the source structure and the drain structure; and
a first embedded epitaxial structure disposed in the drain LDD region and between the gate structure and the heavily doped drain region.

2. The semiconductor transistor structure according to claim 1, wherein the first embedded epitaxial structure comprises an undoped epitaxial SiGe layer or an undoped epitaxial SiP layer.

3. The semiconductor transistor structure according to claim 1, wherein the first embedded epitaxial structure comprises an epitaxial SiGe layer or an epitaxial SiP layer doped with dopants having the first conductivity type.

4. The semiconductor transistor structure according to claim 1, wherein the first embedded epitaxial structure has a thickness that is smaller than a junction depth of the drain LDD region.

5. The semiconductor transistor structure according to claim 1, wherein the first embedded epitaxial structure has a thickness that is greater than or equal to a junction depth of the drain LDD region.

6. The semiconductor transistor structure according to claim 1, wherein the gate structure comprises a first sidewall spacer, wherein the first sidewall spacer overlaps with the drain LDD region.

7. The semiconductor transistor structure according to claim 6, wherein the first embedded epitaxial structure is disposed between the first sidewall spacer and the heavily doped drain region.

8. The semiconductor transistor structure according to claim 1 further comprising:
a drain silicide layer disposed on the heavily doped drain region, wherein the drain silicide layer is not in direct contact with the first embedded epitaxial structure.

9. The semiconductor transistor structure according to claim 1 further comprising:
a second embedded epitaxial structure disposed in the source LDD region and between the gate structure and the heavily doped source region.

10. The semiconductor transistor structure according to claim 9, wherein the second embedded epitaxial structure comprises an epitaxial SiGe layer or an epitaxial SiP layer.

11. A method for forming a semiconductor transistor structure, comprising:
providing a substrate having a first conductivity type;
forming an active area on the substrate, wherein the active area is surrounded by a trench isolation region;
forming a source structure in the active area, wherein the source structure comprises a source lightly doped drain (LDD) region having a second conductivity type and a heavily doped source region having the second conductivity type within the source LDD region;
forming a drain structure in the active area and spaced apart from the source structure, wherein the drain structure comprises a drain lightly doped drain (LDD) region having the second conductivity type and a heavily doped drain region having the second conductivity type within the drain LDD region;
forming a gate structure on the active area and between the source structure and the drain structure; and
forming a first embedded epitaxial structure in the drain LDD region and between the gate structure and the heavily doped drain region.

12. The method according to claim 11, wherein the first embedded epitaxial structure comprises an undoped epitaxial SiGe layer or an undoped epitaxial SiP layer.

13. The method according to claim 11, wherein the first embedded epitaxial structure comprises an epitaxial SiGe layer or an epitaxial SiP layer doped with dopants having the first conductivity type.

14. The method according to claim 11, wherein the first embedded epitaxial structure has a thickness that is smaller than a junction depth of the drain LDD region.

15. The method according to claim 11, wherein the first embedded epitaxial structure has a thickness that is greater than or equal to a junction depth of the drain LDD region.

16. The method according to claim 11, wherein the gate structure comprises a first sidewall spacer, wherein the first sidewall spacer overlaps with the drain LDD region.

17. The method according to claim 16, wherein the first embedded epitaxial structure is disposed between the first sidewall spacer and the heavily doped drain region.

18. The method according to claim 11 further comprising:
forming a drain silicide layer disposed on the heavily doped drain region, wherein the drain silicide layer is not in direct contact with the first embedded epitaxial structure.

19. The method according to claim 11 further comprising:
forming a second embedded epitaxial structure disposed in the source LDD region and between the gate structure and the heavily doped source region.

20. The method according to claim 19, wherein the second embedded epitaxial structure comprises an epitaxial SiGe layer or an epitaxial SiP layer.
